(19) United States
(12) Patent Application Publication
(10) Pub. No.: US 2025/0250408 A1
(43) Pub. Date: Aug. 7, 2025

(54) ARTICLES FOR ATTENUATION OF ELECTROMAGNETIC RADIATION

(71) Applicant: NEMO NANOMATERIALS LTD., Petach Tikva (IL)

(72) Inventors: Ilana HAYMOV, Netanya (IL); Maayan MIZRAHI-DAGAN, Bene Atarot (IL); Yehonatan ANTEBI, Herzelia (IL); Smadar KORIN, Ein Habsor (IL); Dmitry LEKHTMAN, Afula (IL); Moran BEN BASAT, Tel Aviv (IL); Yair SINGER, Ramat Gan (IL); Liran GAMLIEL, Ramat Gan (IL); Tsafrir ELIYAHU, Givat Shmuel (IL)

(73) Assignee: NEMO NANOMATERIALS LTD., Petach Tikva (IL)

(21) Appl. No.: 18/856,620

(22) PCT Filed: Apr. 13, 2023
(86) PCT No.: PCT/IL2023/050396

§ 371 Date: Oct. 13, 2024

(30) Foreign Application Priority Data
Apr. 13, 2022 (IL) 292256

(51) Int. Cl. C08K 3/04; H01Q 1/52

(52) U.S. Cl. CPC C08K 3/041; H01Q 1/526; C08K 2201/011

(57) ABSTRACT

An article comprising a wall, wherein the wall comprises a composition a polymeric matrix and a plurality of CNTs homogenously dispersed within said polymeric matrix is provided, wherein the polymeric matrix comprises a thermoplastic polymer in a form of a three-dimensional interconnecting network; a weight portion of the CNT relative to the polymeric matrix is between 0.00001 and 5%; and the polymeric matrix further comprises a surfactant. Further, the article of the invention is configured for attenuation of electromagnetic radiation.

### CROSS REFERENCE

This application claims the benefit of priority of Israeli Patent Application No. 292256, filed on Apr. 13, 2022, the content of which is incorporated herein by reference in its entirety.

### FIELD OF THE INVENTION

The present invention is in the field of polymeric articles comprising carbon nano-particles and uses thereof such as for attenuation of electromagnetic radiation.

### BACKGROUND OF THE INVENTION

Various composite materials comprising electrically conductive additives (such as carbon nano-tubes, carbon fiber and metallic particles) dispersed within thermoplastic polymeric insulating matrices and characterized by an enhanced electrical conductivity have been the subject of both theoretical and experimental studies over the last decades, due to their wide diversity of applications in electrical and electronic industries. Specifically, Electromagnetic Interference (EMI) attenuation or shielding properties of such composites have been evaluated.

Most of the EMI shielding composites known in the art, require high amount of the conductive additives and tedious processing, thus affecting the industrial feasibility of articles comprising such composites. Accordingly, there is an unmet need to reduce the concentration of the conductive additives within the composite materials for increasing cost effectiveness, to obtain a composite material which is (i) processable by conventional means such as extrusion and molding; and (ii) substantially retains the initial mechanical properties of the thermoplastic polymer.

### SUMMARY OF THE INVENTION

According to one aspect of the invention, there is provided an article comprising a wall, the wall comprises a polymeric matrix and a plurality of CNTs homogenously dispersed within the polymeric matrix, wherein the polymeric matrix comprises a thermoplastic polymer; a weight portion of the CNT relative to the polymeric matrix is between 0.00001 and 5%; the polymeric matrix further comprises a surfactant; and the article is configured for attenuation of an electromagnetic radiation at a wavelength range of between 1 kHz and 150 GHz. In one embodiment, the CNT comprises a single-wall CNT. In one embodiment, the polymeric matrix comprises a thermoplastic polymer in a form of a three-dimensional interconnecting network.

In one embodiment, the matrix is devoid of coalesced particles of the thermoplastic polymer.

In one embodiment, the thermoplastic polymer is characterized by a surface resistivity of at least 10¹⁰ ohm*cm.

In one embodiment, the article is characterized by a surface resistivity of at least 10² ohm*cm.

In one embodiment, the wall is characterized by a thickness between 100 nm and 10 mm.

In one embodiment, a weight ratio of the CNTs per area of the article is between 0.05 and 75 g/m² at a thickness of 40 μm-1 mm.

In one embodiment, a w/w ratio of the surfactant to the CNT within the wall is between 10:1 and 0.5:1.

In one embodiment, a w/w ratio of the surfactant to the polymer within the wall is between 0.00001% and 10%.

In one embodiment, the thermoplastic polymer is characterized by a melting temperature of at least 100° C.

In one embodiment, the article further comprises an inorganic material in a form of (i) fibers; (ii) particulate matter, or both.

In one embodiment, the inorganic material comprises any one of glass, metal, mineral and ceramic, or any combination thereof.

In one embodiment, the article is in a form of a film.

In one embodiment, the article further comprising an additional layer in contact with at least one surface of the wall.

In one embodiment, the additional layer comprises a polymer, and optionally comprises a high strength polymer, an inorganic material or both.

In one embodiment, the article is bondable to a substrate, wherein the bondable is via physical or chemical adhesion, or melting.

In one embodiment, the attenuation is at least 5 dB, as compared to a similar article devoid of the CNT.

In one embodiment, the attenuation is at least 10 dB at a wavelength of the electromagnetic radiation ranging between 1 and 110 GHz.

In one embodiment, each of (i) CNT and (ii) surfactant is present within the wall at a w/w concentration of between 0.00001% and 2%; and wherein the article is characterized by surface resistivity of between 10² and 10¹² ohm*cm.

In one embodiment, the article is manufactured by a method comprising any of: extrusion, injection, hot blown film, and molding or any combination thereof.

In one embodiment, the wall substantially maintains property of the thermoplastic polymer devoid of the surfactant and the CNT, wherein the property is any one of: tensile strength, Young's modulus, elongation at break, melt strength or any combination thereof.

### BRIEF DESCRIPTION OF THE FIGURES

The invention will now be described in relation to certain examples and embodiments with reference to the following illustrative figures so that it may be more fully understood. In the drawings:

FIG. 1A is a graph presenting EMI attenuation of an exemplary article of the invention composed of polyamide 6 with about 1% w/w of CNT (**), versus an article having substantially the same chemical composition and characterized by substantially non-homogenous distribution of CNTs (*).

FIGS. 1B-1C represent images of an exemplary plaque of the invention of (1B) and of a control plaque (1C). As presented in FIG. 1C, the CNT aggregates are visually detectable on the article's surface (white arrows), indicating a non-homogenous distribution of CNTs.

FIG. 2 is a schematic illustration of the EMI attenuation measurement, as described herein.

### DETAILED DESCRIPTION

In one aspect of the invention, there is provided an article comprising a composition, wherein the composition comprises a polymeric matrix and a plurality of carbon nano tubes (CNT) s homogenously dispersed (or uniformly distributed) within the polymeric matrix, wherein the polymeric matrix comprises a thermoplastic polymer; a weight portion of the CNT within the composition is between 0.00001 and 5%; and the composition further comprises a surfactant. In some embodiments, the composition and/or the article is an extrudate. In some embodiments, the article is shapeable via a process selected from extrusion, injection, hot blown film, molding (e.g., cast molding, compression molding, rotational molding) or any combination thereof. In some embodiments, the article of the invention is configured for attenuation of electromagnetic radiation at a wavelength range of between 1 KHz and 150 GHz. The term “wavelength range” as used herein, encompasses any one of sub ranges and any one of distinct wavelength numbers within the range disclosed above.

In some embodiments, the terms “composition” and “composition of the invention” are used herein interchangeably and refer to a plurality of CNTs (e.g., SWCNTs) embedded or incorporated within the polymeric matrix, and further comprising the surfactant, as described herein. In some embodiments, the composition of the invention is composed essentially of the thermoplastic polymer, the CNT, and the surfactant, wherein the thermoplastic polymer, the CNT and the surfactant including ratios and/or concentrations thereof within the composition, are as described herein.

In some embodiments, the article is a solid. In some embodiments, the article comprises a polymeric matrix and a plurality of CNTs (e.g., SWCNTs) embedded or incorporated therewithin. In some embodiments, the plurality of CNTs (e.g., SWCNTs) are homogenously distributed within the matrix.

In some embodiments, the article comprises a wall, wherein the wall is composed of the composition of the invention (e.g., composed essentially of the polymeric matrix and a plurality of CNTs embedded or incorporated therewithin). In some embodiments, the wall is radiation attenuator, wherein radiation refers to electromagnetic radiation at a wavelength range between 1 KHz and 150 GHz, including any range between. In some embodiments, the wall is in a form of a homogenous layer (e.g. a single layered wall or a multi-layered wall). In some embodiments, the wall is a composite material, as disclosed hereinbelow. In some embodiments, the wall is a solid single layered wall, or a multi-layered wall and consisting essentially of the composite material, wherein the composite material is or comprises the composition of the invention. In some embodiments, at least 90%, at least 95%, at least 97%, at least 99%, between 90 and 100%, between 95 and 100%, between 90 and 99%, between 95 and 99%, between 97 and 100%, between 97 and 99% by weight of the wall consist of the composition of the invention.

In some embodiments, the wall is characterized by a thickness between 100 nm and 10 cm, between 100 nm and 1 μm, between 1 μm and 10 cm, between 10 μm and 10 cm, between 10 μm and 5 cm, between 20 μm and 10 cm, between 30 μm and 10 cm, between 40 μm and 10 cm, between 50 μm and 10 cm, between 100 μm and 10 cm, between 10 μm and 1 cm, between 1 and 10 cm, between 1 and 5 cm, between 5 and 10 cm, between 50 μm and 5 cm, between 50 μm and 1 cm, between 50 μm and 3 cm, including any range between.

In some embodiments, the wall and/or the article is characterized by a length/width dimension between 0.1 cm an 100 m, between 1 cm an 100 m, between 1 cm an 1 m, between 1 an 100 m, between 1 an 10 m, between 10 m an 100 m, including any range between.

In some embodiments, each of the plurality of CNTs is in contact with or bound to one or more surfactant molecules. In some embodiments, the surfactant molecules substantially prevent CNT aggregation. In some embodiments, the surfactant enhances compatibility of the CNT and the polymeric matrix. In some embodiments, the surfactant enhances stability of the composition. In some embodiments, the surfactant enhances or induces dispersibility of the CNT within the polymeric matrix. In some embodiments, the surfactant prevents separation of CNT and the thermoplastic polymer.

In some embodiments, the polymeric matrix comprises the thermoplastic polymer, as described hereinbelow. In some embodiments, the polymeric matrix is an intertwined matrix composed of randomly distributed polymeric chains and surfactant molecules. In some embodiments, the polymeric chains are in contact with surfactant molecules, thereby forming the matrix. In some embodiments, the matrix comprises a three-dimensional network of randomly distributed polymeric chains. In some embodiments, the polymeric chains are randomly distributed within the matrix. In some embodiments, the matrix is substantially devoid of aligned or oriented polymeric chains. In some embodiments, the matrix is substantially devoid of polymeric chains aligned or oriented in a specific direction. In some embodiments, the randomly distributed polymeric chains and the surfactant form a three-dimensional mesh structure comprising a void space between the chains. In some embodiments, the polymeric chains are randomly distributed within the matrix thus forming a plurality of pores (or void space). In some embodiments, the matrix further includes any materials incorporated within and/or interposed between the layers. In some embodiments, the matrix is devoid of coalesced polymeric particles. In some embodiments, the matrix is an amorphous matrix.

In some embodiments, the polymeric matrix comprises the thermoplastic polymer, as described hereinbelow. In some embodiments, the thermoplastic polymer molecules composing the polymeric matrix are chemically identical polymers. In some embodiments, the polymeric matrix comprises a plurality of chemically distinct polymers. In some embodiments, the polymeric matrix comprises a mixture of chemically distinct polymeric species.

In some embodiments, the thermoplastic polymer of the invention forms a matrix, wherein the plurality of CNTs (e.g., SWCNTs) are in contact with or bound thereto. In some embodiments, the plurality of CNTs (e.g., SWCNTs) are physisorbed and/or chemisorbed on or within the polymeric matrix. In some embodiments, bound is via a non-covalent bond. In some embodiments, the plurality of CNTs (e.g., SWCNTs) are encapsulated by the matrix. In some embodiments, the plurality of CNTs (e.g., SWCNTs) provide reinforcement and additional physical properties to the composite material (e.g., attenuation of electromagnetic radiation). In some embodiments, the plurality of CNTs (e.g., SWCNTs) induce or enhance electrical conductivity of the article of the invention. In some embodiments, the plurality of CNTs provide EMI shielding properties to the wall.

In some embodiments, the term “bound” refers to any non-covalent bond or interaction, such as electrostatic bond, dipol-dipol interaction, van-der-walls interaction, ionotropic interaction, hydrogen bond, hydrophobic interactions, pi-pi stacking, London forces, etc. In some embodiments, the non-covalent bond or interaction is a stable bond or interaction, wherein stable is as described herein.

In some embodiments, the article or the wall of the article is a composite material. In some embodiments, the article of the invention is a solid composite. In some embodiments, the article of the invention is in a form of a layered composite. In some embodiments, the entire of the article or the composite material (also used herein as the “composite”) of the invention is substantially homogenous.

As used herein, “composite material” is a material produced from two or more constituent materials with notably dissimilar chemical or physical properties that, when merged, create a material with properties, unlike the individual elements.

In some embodiments, a composite is referred to a substantially uniform material which cannot be easily separated into individual constituents (e.g., the CNT, the surfactant, and the thermoplastic polymer of the invention). In some embodiments, a composite is substantially devoid of phase separation or disintegration (also referred to herein as “stable” composite). In some embodiments, a composite is substantially devoid of a multi-layered structure. As one of skilled in the art will appreciate, there are three types of composites (e.g., nanocomposites): unintercalated (micro composite), intercalated, or exfoliated, nanocomposites.

In some embodiments, a homogenous composite as used herein, comprises CNTs substantially uniformly distributed within the matrix. In some embodiments, a homogenous composite as used herein, comprises CNTs substantially uniformly embedded within the matrix. In some embodiments, a homogenous composite as used herein is substantially devoid of CNT aggregates (or agglomerates). In some embodiments, a homogenous composite as used herein, comprises not more than 20%, not more than 15%, not more than 10%, not more than 5%, not more than 3%, not more than 1% of aggregates including any range between, by weight relative to the total CNT content of the composite material of the invention.

In some embodiments, a homogenous composite as used herein, comprises not more than 20%, not more than 15%, not more than 10%, not more than 5%, not more than 3%, not more than 1% of aggregates including any range between, relative to the total CNT content within a cross-section of the composite material. One skilled in the art will appreciate, that the aggregation degree of the CNTs can be assessed by analyzing a micro-structure of the material, including but not limited to TEM or SEM micrographs. In some embodiments, at least 70%, at least 80%, at least 90%, at least 92%, at least 95%, at least 97%, at least 99% of the CNTs of the composite material, are organized in a plurality of distinct domains (or distinct clusters), wherein each domain is characterized by a width dimension (or cross-section) and/or length dimension of between 1 and 500 nm, between 1 and 100 nm, between 1 and 200 nm, between 1 and 10 nm, between 1 and 50 nm, between 10 and 500 nm, between 10 and 100 nm, between 50 and 500 nm, between 50 and 100 nm, between 100 and 500 nm, between 50 and 200 nm, or less than 10 μm, less than 5 μm, less than 1 μm, including any range between.

In some embodiments, a CNT aggregate is characterized by at least one dimension (e.g., thickness) of at least 1 μm, at least 5 μm, at least 10 μm, at least 50 μm, at least 100 μm, at least 500 μm including any range between. In some embodiments, at least one dimension of the aggregate refers to an average value.

Homogeneity of the composite material of the invention (e.g., presence of CNT aggregates) can be assessed by using an appropriate microscopic analysis of the material surface, such as by TEM, SEM etc. The analysis of micrographs (e.g., TEM and/or SEM micrographs) can be performed for example via an image processing software, which is well-known in the art. Furthermore, homogeneity can be assessed by testing the composition of the article in at least 3 different location (e.g., determining the concentration of CNT and/or surfactant). It is postulated that the standard deviation of the measured concertation values is not more than 20%, not more than 10%, not more than 5%, not more than 1%, including any range between.

Alternatively, homogeneity can be assessed by testing the EMI (Electromagnetic Interference) attenuation or shielding properties of the composition or article. The inventors surprisingly found that a substantially inhomogeneous distribution of the CNTs within the wall of an exemplary article of the invention results in an inferior EMI shielding, as compared to the article of the invention characterized by a homogenous CNT distribution. Furthermore, it has been found that an article having inhomogeneous distribution of the CNTs therewithin has substantially the same (e.g., +10%, or +20%, or even less) EMI attenuation as the pristine polymer, e.g., the same polymer devoid of CNT.

In some embodiments, the article or the composition of the invention consists essentially of a thermoplastic polymer, CNT, and the surfactant as described herein. In some embodiments, at least 50%, at least 60%, at least 70%, at least 80%, at least 85%, at least 90%, at least 93%, at least 95%, at least 97%, at least 99%, including any range between, by weight of the article of the invention is composed of the thermoplastic polymer. In some embodiments, at least 80%, at least 90%, at least 95%, at least 99%, at least 99.9%, of the polymeric matrix is composed of the thermoplastic polymer.

In some embodiments, CNT and/or the surfactant (and optionally any additional component of the composition) are miscible or compatible with the thermoplastic polymer in a molten state. In some embodiments, the thermoplastic polymer in a molten state is miscible or compatible with the additional components of the composition, so as to form a composite material (e.g., upon cooling thereof below the glass transition temperature of the thermoplastic polymer). In some embodiments, the thermoplastic polymer in a molten state is compatible with the CNT, such that the resulting mixture is substantially devoid of phase separation and/or aggregation.

In some embodiments, the thermoplastic polymer in a molten state is miscible with additional components of the composition, so as to result in a homogenous composite material (e.g., after solidifying of the mixture). In some embodiments, the thermoplastic polymer, and the CNT and optionally the surfactant are capable of forming a homogenous composite.

In some embodiments, the thermoplastic polymer has a melting point of greater than 100° C., 110° C., 120° C., 150° C., 150° C., 200° C., 250° C., 300° C., 350° C., 400° C., 500° C., 600° C., including any range or value therebetween.

In some embodiments, the thermoplastic polymer has a melting point of between 10° and 650° C., between 100 and 200° C., between 20° and 400° C., between 400 and 650° C., including any range or value therebetween.

In some embodiments, the thermoplastic polymer is selected from polyamide (PA) (e.g. PA 6, PA 6.6 etc.), polystyrene, acrylonitrile, butadiene styrene, polyacrylate, polycarbonate, polyacrylate ester, polymethacrylate, polyacrylamide, polyolefin, poly(bisphenol A-co-carbonate), poly(bisphenol A-co-terephthalate), polyvinyl alcohol, polyvinyl chloride and polyacrylonitrile, polyphenylene, polyether ether ketone, polyphenylene sulfide, polyetherimide, polyether sulfone, polyacetal, polyoxymethylene, polyphenylene oxide, polysulphone, polyimide, polyamide imide, polytetrafluoroethylene, including any copolymer or any combination thereof. In some embodiments, the polymer comprises a thermoplastic resin (e.g., short-chain polymers or oligomers).

In some embodiments, the thermoplastic polymer comprises an acrylate-based polymer. In some embodiments, the acrylate-based polymer is selected from the group comprising polyacrylate, polyacrylate ester, polymethacrylate, polyetylmethacrylate, polymethacrylate ester, polyetylmethacrylate ester including any copolymer or any combination thereof.

In some embodiments, the thermoplastic polymer comprises a polystyrene and/or a derivative thereof (e.g., a substituted polystyrene such as poly(halo-styrene), poly(alkyl-styrene), etc.).

In some embodiments, the thermoplastic polymer comprises a polyolefin or a mixture of polyolefins. Non-limiting examples of polyolefins include but are not limited to: polyethylene (PE), LDPE, MDPE, HDPE, polypropylene (PP), polybutene, polyethylene-butene copolymer, polyethylene-propylene copolymer, atactic poly-α-olefin (APAO), amorphous poly-α-olefin (APAO), and syndiotactic polypropylene (SPP). Other polyolefins are well-known in the art.

In some embodiments, the thermoplastic polymer comprises a polyamide or a mixture of polyamides, such as Nylon. Various polyamides are known in the art, such as PA 6, PA 12, PA 6,6, etc.

In some embodiments, the thermoplastic polymer forming or defining the polymeric matrix is substantially devoid of electrical conductivity. In some embodiments, the thermoplastic polymer is characterized by a volume resistivity of at least 10¹⁰ ohm*cm, at least 10¹¹ ohm*cm, at least 10¹³ ohm*cm, at least 10¹⁴ ohm*cm, at least 10¹⁵ ohm*cm, including any range between. In some embodiments, the thermoplastic polymer is a non-conductive polymer. In some embodiments, the thermoplastic polymer is substantially devoid of a conductive polymer.

In some embodiments, the thermoplastic polymer is characterized by a surface resistivity of at least 10¹⁰, ohm*cm, at least 10¹¹ ohm*cm, at least 10¹³ ohm*cm, at least 10¹⁴ ohm*cm, at least 10¹⁵ ohm*cm, including any range between.

In some embodiments, the thermoplastic polymer is characterized by a surface resistivity of greater than 1.05E+06, greater than 1.05E+09, greater than 1.05E+12 ohm, including any range between.

In some embodiments, the composition of the invention comprises the CNT (e.g., SWCNT) and the surfactant embedded within the polymeric matrix.

In some embodiments, the CNT is or comprises a carbon nano-structure (e.g., a single carbon nano-structure specie or a plurality of distinct carbon nano-structure species. The term “carbon nano-structure” is well known to a skilled artisan and refers inter alia to 2D carbon material, such as carbon fiber, carbon nanotube (single wall or multi wall, linear or branched), carbon black, graphene, and fullerene, or any combination thereof.

In some embodiments, the CNT is or comprises a single-wall carbon nano-tube (SWCNT). In some embodiments, the CNT is electrically conductive CNTs (e.g., electrically conductive SWCNT). In some embodiments, the CNT optionally comprises a multi-wall carbon nano-tube (MWCNT). In some embodiments, the CNT comprises SWCNT and optionally comprises an additional carbon nano-structure.

In some embodiments, the CNT is characterized by an aspect ratio between 130 and 10,000, between 130 and 200, between 130 and 1,000, between 1000 and 5,000, between 5000 and 10,000, between 130 and 7,000, between 7000 and 10,000, including any range between.

In some embodiments, a w/w concentration of the CNT within the article is between 0.00001% and 5%, between 0.00005% and 5%, between 0.00001% and 0.00005%, between 0.00001% and 0.0001%, between 0.00001% and 0.001%, between 0.0001% and 5%, between 0.0001% and 2%, between 0.001% and 5%, between 0.001% and 2%, between 0.001% and 1%, between 0.001% and 0.005%, between 0.005% and 0.01%, between 0.01% and 5%, between 0.01% and 2%, between 0.01% and 1%, between 0.01% and 0.5%, between 0.01% and 0.05%, between 0.05% and 0.1%, between 0.1% and 0.5%, between 0.5% and 1%, between 1% and 2%, between 2% and 3%, between 3% and 5%, between 5% and 10%, including any range therebetween. In some embodiments, a w/w concentration of the CNT within the article refers to the weight portion of the CNT relative to the polymeric matrix within the article.

In some embodiments, a w/w concentration of the CNT within the article (also referred to herein as the effective amount) is sufficient for providing energy attenuating properties to the article, wherein attenuation is as described herein. In some embodiments, energy refers to electromagnetic radiation. In some embodiments, a w/w concentration of the CNT within the article is sufficient for enhancing attenuation of electromagnetic radiation by the article of the invention, wherein enhancing refers to energy attenuation compared to a control. In some embodiments, a control is a similar article devoid of CNTs. In some embodiments, a control is a similar article comprising CNTs which are non-homogenously distributed within the polymeric matrix. In some embodiments, a control is a similar thermoplastic polymer devoid of CNT and/or surfactant.

A skilled artisan will appreciate that the energy attenuating properties of the article are strongly dependent on the CNT concentration, and their distribution in the polymeric matrix. The main challenge in development of articles characterized by energy attenuation and at the same time having a reduced weight (e.g., as compared to metal-based electromagnetic radiation shields). Furthermore, it is advantageous to keep the CNT concentration as low as possible, thus contributing to the cost-efficiency of the article.

As used herein the term “attenuation” refers to the reduction of the intensity (or amplitude) of the electromagnetic waves (or electromagnetic radiation). Specifically, intensity reduction refers to electromagnetic waves propagating through the wall (e.g., in a direction perpendicular to the longitudinal axis of the article or of the wall). As used herein the term “attenuation” refers to the ability of the article of the invention to reduce the intensity of the incoming electromagnetic radiation, wherein reduction is relative to the initial intensity of the incoming radiation.

One skilled in the art will appreciate that attenuation is induced by reflection, absorption, or dissipation of the electromagnetic radiation by at least one wall of the article of the invention.

Attenuation of exemplary articles of the invention can be measured according to a method described in the Examples section.

In some embodiments, reduction, or attenuation (including any grammatical form thereof) comprises at least 5 times, at least 10 times, at least 100 times, at least 1000 times, at least 10⁵ times, at least 10⁷ times, at least 10¹⁰ times, at least 10¹⁵ times, at least 10²⁰ times, at least 10³⁰ times reduction including any range between, compared to a control. As used here in the term “control” refers to an article comprising the pristine polymer and having substantially the same dimension.

In some embodiments, reduction, or attenuation (including any grammatical form thereof) is by about 2 dB, about 5 dB, about 10 dB, about 15 dB, about 20 dB, about 25 dB, about 30 dB, by at least 2 dB, at least 5 dB, at least 10 dB, at least 15 dB, at least 20 dB, at least 25 dB, at least 30 dB, including any range between.

In some embodiments, the effective amount of the CNT within the wall of the article or within the article is at most 5%, at most 3%, at most 2%, at most 1%, at most 0.5%, at most 0.1%, at most 0.05%, at most 0.01% w/w, at most 0.001% w/w, at most 0.0001% w/w, including any range therebetween.

In some embodiments, the effective amount of the CNT within the wall of the article or within the article is at least 0.00001%, at least 0.00005%, at least 0.0001%, at least 0.0005%, at least 0.001%, at least 0.005%, including any range therebetween.

In some embodiments, the effective amount of the CNT within the wall of the article or within the article is between 0.00001 and 5%, between 0.00005 and 5%, between 0.0001%, and 5%, between 0.0005% and 5%, between 0.001 and 5%, between 0.005 and 5%, between 0.005 and 3%, between 0.01 and 1%, between 0.05 and 2%, including any range in between.

In some embodiments, the content of the non-SWCNT carbon nanostructures (e.g., MWCNT, etc.) within the article and/or the composition described herein, is at most 30%, at most 25%, at most 20%, at most 15%, at most 10%, at most 5%, at most 1% including any range between, by weight relative to the total CNT content of the article.

In some embodiments, the total CNT content is referred to herein, as a weight portion of the SWCNT and optionally at least one an additional carbon nanostructure (such as MWCNT, carbon black, fullerene, graphene, etc.) within the article of the invention.

In some embodiments, the composition is substantially devoid of an additional carbon nano-particle. In some embodiments, the composition is substantially devoid of an inorganic material (e.g., metal, glass, mineral including any particles, or any fibers thereof). In some embodiments, the composition is substantially devoid of a fiber (e.g., carbon fiber etc.). In some embodiments, the terms carbon nanostructure and carbon nano-particle are used herein interchangeably.

In some embodiments, the effective amount of the CNT within the article comprises a weight portion of the CNT per area of the article between 0.05 and 75 g/m², between 0.05 and 0.1 g/m², between 0.1 and 75 g/m², between 0.1 and 1 g/m², between 1 and 75 g/m², between 1 and 10 g/m², between 0.1 and 10 g/m², between 0.1 and 20 g/m², between 0.1 and 30 g/m², between 0.1 and 40 g/m², between 0.1 and 50 g/m², between 0.1 and 70 g/m², between 1 and 50 g/m², between 1 and 30 g/m², between 10 and 75 g/m², between 10 and 30 g/m², between 10 and 50 g/m², between 20 and 75 g/m², between 20 and 50 g/m², including any range between, wherein the weight portion refers to an article with a thickness ranging between 40 μm and 1 mm.

In some embodiments, the effective amount of the CNT within the article is at least 0.1, at least 1, at least 5, at least 10, at least 20, at least 30, at least 40 g/m², including any range between; wherein the effective amount portion refers to an article with a thickness ranging between 40 μm and 1 mm.

In some embodiments, the effective amount of the CNT within the article is at most 50, at most 40, at most 30, at most 20, at most 10, at most 5, at most 1, at most 0.5, at most 0.05 g/m², including any range between; wherein the effective amount portion refers to an article with a thickness ranging between 40 μm and 1 mm.

In some embodiments, the effective amount of the CNT is sufficient for obtaining an article configured for substantially reducing or attenuating electromagnetic radiation (as disclosed herein) and wherein the article is substantially devoid of electrical conductivity.

In some embodiments, the electrical conductivity of the article is by at least 10, at least 100, at least 1000, at least 10,000, at least 100,000 times, at least 1,000,000 times, at least 10,000,000 times greater than the electrical conductivity of the pristine polymer, including any range therebetween. In some embodiments, the electrical conductivity of the article is substantially the same as the electrical conductivity of the pristine polymer. In some embodiments, the electrical conductivity refers to a surface conductivity or to a volume conductivity.

In some embodiments, the article of the invention is characterized by volume resistivity of between 10¹³ and 1 ohm*cm, between 10¹³ and 10¹² ohm*cm, between 10¹² and 10¹⁰ ohm*cm, between 10¹⁰ and 10⁸ ohm*cm, between 10⁸ and 10⁶ ohm*cm, between 10⁶ and 10⁴ ohm*cm, between 10⁴ and 10² ohm*cm, between 10² and 1 ohm*cm, including any range therebetween.

In some embodiments, the article of the invention is characterized by surface resistivity of between 10¹³ and 1 ohm*cm, between 10¹³ and 10¹² ohm*cm, between 10¹² and 10¹⁰ ohm*cm, between 10¹⁰ and 10⁸ ohm*cm, between 10⁸ and 10⁶ ohm*cm, between 10⁶ and 10⁴ ohm*cm, between 10⁴ and 10² ohm*cm, between 10² and 1 ohm*cm, including any range therebetween. In some embodiments, the surface resistance is measured according to ANSI/ESD STM11.11.

In some embodiments, the article of the invention is characterized by surface resistivity of at least 10², at least 10³, at least 10⁵, at least 10⁷, at least 10¹⁰, at least 10¹² ohm*cm, including any range therebetween.

In some embodiments, the composition of the invention comprises an effective amount of the surfactant. In some embodiments, the effective amount is so as to substantially prevent aggregation or agglomeration of CNTs, and/or to increase compatibility of the CNT with the thermoplastic polymer, thereby resulting in a stable article. In some embodiments, the effective amount is so as to induce homogenous distribution of CNTs within the article or polymeric matrix of the invention.

In some embodiments, the effective amount of the surfactant comprises a w/w concentration of the surfactant relative to the thermoplastic polymer within the wall of the article of between 0.001% and 30%, between 0.00001% and 10%, between 0.00001% and 5 between 0.00005% and 5%, between 0.0001% and 10%, between 0.0001% and 0.001%, between 0.001% and 15%, between 0.003% and 15%, between 0.005% and 15%, between 0.01% and 15%, between 0.001% and 10%, between 0.001% and 5%, between 0.01% and 15%, between 0.01% and 10%, between 0.01% and 5%, between 0.05% and 15%, between 0.05% and 10%, between 0.05% and 5%, between 0.05% and 0.1%, between 0.1% and 0.3%, between 0.3% and 0.5%, between 0.5% and 0.7%, between 0.7% and 1%, between 0.001% and 0.01%, between 0.01% and 0.1%, between 0.1% and 1%, between 1% and 5%, between 5% and 10%, between 10% and 20%, between 10% and 15%, between 15% and 20%, between 1% and 10%, between 10% and 30%, including any range between.

In some embodiments, a w/w concentration of the surfactant within the article is less than 1%, less than 0.7%, less than 0.5%, less than 0.3%, less than 0.1%, less than 0.05%, less than 0.01%, less than 0.005%, less than 0.001%, less than 0.0001%, less than 0.00005%, including any range between, by total weight of the article.

In some embodiments, the effective amount of the surfactant comprises a w/w ratio between the surfactant and the CNT (e.g. SWCNT) within the article (or within the wall) is between 20:1 and 10:1, between 10:1 and 0.5:1, between 10:1 and 1:1, between 10:1 and 8:1, between 8:1 and 5:1, between 5:1 and 3:1, between 3:1 and 2:1, between 9:1 and 7:1, between 7:1 and 5:1, between 5:1 and 3:1, between 3:1 and 1:1, between 3:1 and 0.5:1, between 1:1 and 1:2, including any range between. In some embodiments, the effective amount of the surfactant comprises a w/w ratio between the surfactant and the CNT (e.g., SWCNT) within the article (or within the wall) is between about 3:1 and 1:2.

In some embodiments, the surfactant is characterized by a solubility in an organic solvent (e.g., polar solvent such as iso propyl alcohol, non-polar solvent such as toluene) and/or water of at least 1 g/L, at least 10 g/L, at least 50 g/L, at least 100 g/L, including any range between.

In some embodiments, the surfactant is a cationic surfactant. In some embodiments, the surfactant comprises polyalkylammonium. In some embodiments, the surfactant is or comprises polyalkylammonium-co-polyether.

In some embodiments, the surfactant is or comprises an anionic surfactant (e.g., SDBS, carboxymethyl cellulose CMC) and/or a non-ionic surfactant (e.g., polysiloxane).

In some embodiments, the surfactant is devoid of polyvinyl pyrrolidone (PVP). In some embodiments, the surfactant is devoid of a co-polymer comprising PVP and/or a cellulose or a derivative thereof.

In some embodiments, the surfactant is devoid of a surfactant suitable for implementation in a dispersion polymerization (DP), also assigned as “latex polymerization”.

In some embodiments, the composition or the article of the invention is processable by an extruder. In some embodiments, the composition or the article of the invention is extrudable. In some embodiments, the composition or the article is flowable in a molten state. In some embodiments, the melt flow index (MFI) of the composition or the article of the invention is predetermined by the w/w concentration and/or chemical structure of the CNT and/or of the surfactant.

In some embodiments, the composition of the invention is extrudable, i.e., remains chemically stable and retains its physical properties (e.g., intactness, devoid of phase separation, homogenous distribution of CNT, capability of EMI attenuation, retains its physical strength, etc.) upon exposing the composition of the invention to conditions suitable for extrusion (e.g., elevated pressure and temperature). In some embodiments, the composition of the invention has appropriate rheological properties in a molten state (such as flowability, and/or MFI as described herein).

In some embodiments, an extrudable composition or article is characterized by MFI of between 0.1 and 100, between 0.1 and 1, between 1 and 10, between 10 and 50, between 50 and 100, including any range between.

In some embodiments, the article of the invention can be manufactured and/or processed via extrusion of the composition.

In some embodiments, the article of the invention is manufactured from the composition of the invention. In some embodiments, the term article refers to the composition having a predetermined shaped (e.g., a processed or shaped composition, wherein processed is via a method described herein).

In some embodiments, the composition of the invention is shapeable or formable (e.g., capable of obtaining a predetermined shape) by a process selected from extrusion, injection, hot blown film, molding (e.g., cast molding, compression molding, rotational molding) or any combination thereof.

In some embodiments, the article of the invention further comprises an inorganic material and/or an organic material in a form of fibers and/or particles. In some embodiments, the article of the invention further comprises a single specie of the inorganic material or a plurality of distinct material species. In some embodiments, the inorganic material is in a form of a fiber, a substantially spherically shaped particle (e.g., a nano-particle, a micro-particle or both), a sheet (e.g., a 2D material), or any combination thereof.

In some embodiments, the inorganic or organic material comprises thermoplastic polymer particles or fibers. In some embodiments, the organic material comprises a thermoplastic organic polymer. In some embodiments, the inorganic material comprises a metal, a ceramic, a glass, a super hard material, including any derivative thereof, or any combination thereof.

In some embodiments, the article of the invention comprises one or more walls. In some embodiments, the article of the invention comprises a plurality of walls in contact with or bound to each other. In some embodiments, the one or more walls define a lumen. In some embodiments, the wall is substantially planar or is curved.

In some embodiments, the term wall refers to a structural element of the article, wherein the shape of the wall substantially predefines the shape of the article. In some embodiments, the wall is characterized by a uniform thickness. In some embodiments, the wall is characterized by a non-uniform thickness. In some embodiments, the wall has a 2-D or a 3-D shape. In some embodiments, the wall is any of a sphere, a hemisphere, a hollow sphere, a cylinder, a hollow cylinder, a hollow hemisphere, a cone, a pyramid, a horseshoe, or any other 3-D shape. In some embodiments, the wall is substantially continuous. In some embodiments, the wall comprises one or more openings or incisions. In some embodiments, the openings are distributed in a form of a pattern on or within the wall. In some embodiments, the wall is a perforated wall. In some embodiments, the openings or perforations are distributed in a form of a pattern on or within the wall. In some embodiments, the wall is in a form of a net.

In some embodiments, the opening or perforations are characterized by a cross-section between 100 μm and 10 cm, between 100 μm and 200 μm, between 100 μm and 500 μm, between 500 μm and 1 mm, between 1 and 5 mm, between 1 and 10 mm, between 1 and 10 cm, including any range between.

In some embodiments, the shape of the wall and/or the pattern of the openings is predetermined by a desired shape and/or dimensions of the EMI shielding area. In some embodiments, the wall and/or article is shaped so as to provide a substantial EMI shielding within a predetermined location. In some embodiments, the wall and/or article is shaped so as to provide a partial EMI shielding within a predetermined location.

In some embodiments, the wall and/or article is shaped so as to result in EMI reflection, EMI dissipation or both. In some embodiments, the wall comprises an outer surface facing the incoming electromagnetic radiation and an inner surface. In some embodiments, the wall provides EMI attenuation at a location in close proximity to the inner surface of the wall, wherein EMI attenuation is as described herein.

In some embodiments, the outer surface of the wall is characterized by predetermined surface roughness. In some embodiments, the outer surface of the wall is a textured surface. In some embodiments, the texture or roughness is characterized by a height dimension ranging between 1 μm and 1 mm, including any range between.

In some embodiments, the article of the invention and/or the wall is characterized by a three-dimensional shape. In some embodiments, the article of the invention and/or the wall has any predefined 3-D shape or structure. In some embodiments, the article of the invention has a regular or an irregular shape.

In some embodiments, the article and/or the wall is in a form of a layer. In some embodiments, the article and/or the wall is in a form of a film. In some embodiments, the film forms a substantially uniform layer. In some embodiments, the film is a solid film. In some embodiments, the article is a solid (e.g., substantially in a solid state and is not flowable) at a temperature below the melting temperature and/or below the glass transition temperature of the thermoplastic polymer composing the article. The melting point of the thermoplastic polymer may vary, depending on the chemical composition, MW and/or density of the thermoplastic polymer.

By “uniform” or “homogenous” when referring to the layer or film, it is meant to refer to size (or thickness) distribution that varies within a range of less than e.g., +50%, +40%, +30%, +20%, +10%, +5%, or less including any value therebetween. Furthermore, the term homogenous refers to homogenous dispersion or distribution of the CNT at the microscopic level within the matrix or composite of the invention.

In some embodiments, the term “layer”, refers to a substantially uniform thickness of a substantially homogeneous substance. In some embodiments, the layer or film comprises a single layer, or a plurality of layers. In some embodiments, the term layer and the term film are used herein interchangeably.

In some embodiments, the wall is in a form of a multi-layered wall. In some embodiments, the wall comprises a first layer and a second layer in contact with an outer surface of the first layer. In some embodiments, the second layer is bound to the first layer. In some embodiments, the second layer is positioned on top of the first layer. In some embodiments, the second layer or the first layer is sandwiched between at least two distinct layers (e.g., of the first layer or of the second layer, respectively). In some embodiments, the second layer and/or the first layer comprises a one or more layers, wherein the layers are the same or different (e.g., having a different chemical composition, or a different dimension).

In some embodiments, the first layer comprises the composition as described herein. In some embodiments, the second layer comprises any of: a polymer, a high strength polymer, an inorganic material, or any combination thereof, wherein any of the materials composing the second layer is independently selected from a homogenous material (e.g., a film), a fiber, particle (e.g., a nano-particle, a micro-particle or both), a sheet (e.g., a 2D material), or any combination thereof.

In some embodiments, the article, or the wall (e.g., in a form of a layer) is bondable to a substrate. In some embodiments, the article is capable of attachment to the substrate, wherein attachment is by physical or chemical adhesion, melting or a combination thereof.

In some embodiments, the article or the wall of the invention is configured for attenuation of electromagnetic radiation at a wavelength range of between 1 KHz and 150 GHz, 1 KHz and 200 GHz, 10 KHz and 150 GHz, 10 KHz and 110 GHz, 10 KHz and 130 GHz, between 0.1 MHz and 150 GHz, between 0.1 MHz and 200 GHz, between 1 MHz and 150 GHz, between 1 MHz and 130 GHz, between 10 MHz and 150 GHz, between 100 MHz and 150 GHz, between 50 MHz and 150 GHz, between 50 MHz and 200 GHz, between 100 MHz and 120 GHz, between 100 MHz and 110 GHz, between 100 MHz and 100 GHz, between 500 MHz and 150 GHz, between 500 MHz and 130 GHz, between 500 MHz and 200 GHz, between 0.1 MHz and 1 MHz, between 1 and 10 MHz, between 10 and 100 MHz, between 100 and 1000 MHz, between 0.1 and 1 GHz, between 1 and 150 GHz, between 0.1 and 150 GHz, between 0.1 and 130 GHz, between 1 and 130 GHz, between 0.1 and 110 GHz, between 1 and 110 GHz, between 1 and 5 GHz, between 5 and 10 GHz, between 1 and 10 GHz, between 10 and 20 GHz, between 20 and 50 GHz, between 50 and 70 GHz between 70 and 90 GHz between 90 and 110 GHz, including any range between. In some embodiments, attenuation of electromagnetic radiation refers to the reduction of the intensity of the electromagnetic radiation, as compared to a control. In some embodiments, attenuation is as described hereinabove.

In some embodiments, the article of the invention is characterized by an attenuation of at least 5 dB, at least 10 dB, at least 15 dB, at least 20 dB, at least 30 dB of the electromagnetic radiation, as compared to a control, wherein the electromagnetic radiation has a wavelength range of between 1 and 150 GHz, between 1 and 120 GHz, between 1 and 130 GHz, between 1 and 110 GHz, including any range between.

In some embodiments, the article of the invention is characterized by a normalized attenuation of between 2 and 10, between 2 and 30, between 5 and 10, between 5 and 20, between 5 and 30, between 5 and 40, between 6 and 8, between 8 and 10 dB*m² per gram of the article, including any range between.

In some embodiments, the wall of the article of the invention comprises a concentration of CNT and of the surfactant independently ranging between 0.00001 and 2%, or between 0.00005 and 2%, and is characterized by a surface resistivity between 10² and least 10¹² ohm*cm, and wherein the wall is characterized by EMI attenuation as described herein.

In some embodiments, the article of the invention is physically stable. In some embodiments, a stable article is substantially devoid of phase separation (e.g., disintegration of the composite accompanied by separation between CNT and the polymeric matrix). In some embodiments, a stable article is substantially devoid of cracking, deformation, or other physical defects. In some embodiments, a stable article substantially retains its shape, dimensions and/or physical properties, such as mechanical strength, electrical conductivity, energy attenuation properties etc.

In some embodiments, a stable article substantially maintains a property of the thermoplastic polymer (e.g., pristine polymer devoid of the CNT and/or the surfactant) substantially composting the article. In some embodiments, the property is a mechanical property selected from tensile strength, Young's modulus, elongation at break, melt strength, or any combination thereof. In some embodiments, the article is characterized by a thermoplastic behavior. In some embodiments, the article is characterized by elasticity. In some embodiments, the article is characterized by substantially the same elasticity as the thermoplastic polymer. As used herein the term “substantially”, when referring to the property of the article, comprises ±1%, ±5%, ±7%, ±10%, ±15%, ±20%, ±30%, relative to the property of the pristine polymer, including any range between.

In some embodiments, the melting or liquefaction point of the article is substantially the same as the melting point of the thermoplastic polymer.

In some embodiments, the article of the invention is manufactured or shaped by providing the composition of the invention under conditions suitable for extrusion, injection, hot blown film, molding (e.g., cast molding, compression molding, rotational molding) or any combination thereof. In some embodiments, the article of the invention is manufactured or shaped by subjecting the composition to any thermoplastic polymer processing method.

In some embodiments, the composition of the invention is manufactured by (i) providing a plurality of particles (also referred to herein as core-shell particles), each particle comprising a polymeric core in contact with a shell comprising CNT and the surfactant, wherein: the polymeric core comprises a thermoplastic polymer; and wherein a size of the particle is between 30 and 2000 μm; and (ii) subjecting the plurality of particles to a process selected from extrusion, injection, hot blown film, molding (e.g. cast molding, compression molding, rotational molding) or any combination thereof. In some embodiments, the plurality of particles are extrudable particles, and wherein the w/w ratio between the thermoplastic polymer the CNT and/or the surfactant is as described herein (with respect to the composition of the invention). A skilled artisan will appreciate that any thermoplastic polymer can by utilized in the core-shell particles. Furthermore, the w/w ratio between the CNT and the thermoplastic polymer within the core-shell particle is predetermined by the desired weight ratio of the CNT within the composition/article of the invention.

In some embodiments, the article is substantially stable (e.g., the article substantially maintains its structural and/or functional properties, such as physical stability, and/or absence of disintegration or erosion of the coating layer) for at least one month (m), at least 2 m, at least 6 m, at least 12 m, at least 2 years (y), at least 3 y, at least 10 y, including any range therebetween, wherein substantially is as described hereinbelow.

In some embodiments, the article is substantially stable upon exposure to a thermal radiation. In some embodiments, the thermal radiation comprises a temperature of between 3° and 100° C., between-50 and 0° C., between 0 and 10° C., between 1° and 30° C., between 3° and 50° C., between 5° and 70° C., between 7° and 100° C., between 10° and 150° C., including any range therebetween. In some embodiments, the thermal radiation comprises a temperature lower than the melting point of the thermoplastic polymer.

As used herein the term “stable” refers to the ability of the article to substantially maintain its structural, physical and/or chemical properties (including inter alia energy attenuation). In some embodiments, the article is referred to as stable, when it substantially maintains its structure (e.g., shape, and/or a dimension such as thickness, length, etc.), wherein substantially is as described herein.

In some embodiments, the coating layer is referred to as stable, when it is substantially devoid of cracks, deformations, or any other surface irregularities.

In some embodiments, the terms “coating” and “coating layer” are used herein interchangeably.

Substrate usable according to some embodiments of the present invention can have, for example, organic or inorganic surfaces, including, but not limited to, glass surfaces; porcelain surfaces; ceramic surfaces; silicon or organosilicon surfaces, metallic surfaces (e.g., stainless steel); polymeric surfaces such as, for example, plastic surfaces, rubbery surfaces, paper; wood; fabric in a woven, knitted or non-woven form; mineral (rock or glass), surfaces, wool, silk, cotton, hemp, leather, plastic surfaces and surfaces comprising or made of polymers, polyamide, inorganic polymers such as silicon rubber or glass; or can comprise or be made of any of the foregoing substances, or any mixture thereof. Exemplary substrates are selected from but are not limited to polymers of polycarbonate, polyesters, polyamide, and metallic foils such as aluminum foil,

In some embodiments, the substrate is in a form of a continuous layer or a woven or a non-woven substrate.

In some embodiments, the article is or comprises any one of: an electromagnetic radiation shield, in the following forms: gaskets, housing, casing, grounding, foams, enclosure, box, tape, foil, fiber, pipe, jacket, a Faraday cage, antenna, display, radar, emitting device in one of the following technologies: wireless communication, wi-fi, blue-tooth, 3G (GSM), 4G (LTE), 5G, 6G, WLAN, NFC, RF, cell-phone, alarm, broadcasting. communication device, cable insulation, cable jacketing, electromagnetic noise filters, sensors, compartment and conformal shielding in PCB's, aircraft systems, wearable electronics, wearable protection gear, electromagnetic radiation manipulation e.g., stealth mode, concealment.

### General

As used herein the term “about” refers to +10%.

The terms “comprises”, “comprising”, “includes”, “including”, “having” and their conjugates mean “including but not limited to”.

The term “consisting of means “including and limited to”.

The term “consisting essentially of” means that the composition, method, or structure may include additional ingredients, steps and/or parts, but only if the additional ingredients, steps and/or parts do not materially alter the basic and novel characteristics of the claimed composition, method, or structure.

The word “exemplary” is used herein to mean “serving as an example, instance or illustration”. Any embodiment described as “exemplary” is not necessarily to be construed as preferred or advantageous over other embodiments and/or to exclude the incorporation of features from other embodiments.

The word “optionally” is used herein to mean “is provided in some embodiments and not provided in other embodiments”. Any particular embodiment of the invention may include a plurality of “optional” features unless such features conflict.

The term “enhancing” or “reducing” is by at least 10%, at least 20%, at least 30%, at least 40%, at least 50%, at least 60%, at least 80%, at least 100%, at least 150%, at least 200%, at least 250%, at least 300%, including any range or value therebetween, compared to a control.

As used herein, the singular form “a”, “an” and “the” include plural references unless the context clearly dictates otherwise. For example, the term “a compound” or “at least one compound” may include a plurality of compounds, including mixtures thereof.

Throughout this application, various embodiments of this invention may be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

Whenever a numerical range is indicated herein, it is meant to include any cited numeral (fractional or integral) within the indicated range. The phrases “ranging/ranges between” a first indicate number and a second indicate number and “ranging/ranges from” a first indicate number “to” a second indicate number are used herein interchangeably and are meant to include the first and second indicated numbers and all the fractional and integral numerals therebetween.

As used herein the term “substantially” refers at least 60%, at least 70%, at least 80%, at least 85%, at least 90%, at least 95%, at least 97%, at least 99%, at least 99.9%, including any rage or value therebetween. In some embodiments, the terms “substantially” and the term “consisting essentially of” are used herein interchangeably.

As used herein the term “method” refers to manners, means, techniques and procedures for accomplishing a given task including, but not limited to, those manners, means, techniques and procedures either known to, or readily developed from known manners, means, techniques and procedures by practitioners of the chemical, pharmacological, biological, biochemical, and medical arts.

As used herein, the term “treating” includes abrogating, substantially inhibiting, slowing, or reversing the progression of a condition, substantially ameliorating clinical or aesthetical symptoms of a condition, or substantially preventing the appearance of clinical or aesthetical symptoms of a condition.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination or as suitable in any other described embodiment of the invention. Certain features described in the context of various embodiments are not to be considered essential features of those embodiments unless the embodiment is inoperative without those elements.

Various embodiments and aspects of the present invention as delineated hereinabove and as claimed in the claims section below find experimental support in the following examples. Reference is now made to the following examples, which together with the above descriptions illustrate some embodiments of the invention in a non-limiting fashion.

### EXAMPLES

### Example 1

An exemplary article of the invention comprising at least one wall composed of the composition of the invention, has been fabricated by extrusion and/or molding of core-shell particles described herein.

Polyamide (Polyamide 6) and SWCNT based core-shell particles have been implemented for the manufacturing of an exemplary article in a form of a plaque. The composition of the core-shell particles was as follows: Polyamide (PA 6) powder, particle size 30-1300 μm (purchased from LANXESS, DOMO, BASF, etc.); SWCNT 1 wt % (outer mean diameter 1.6 nm, length >5 μm, purchased from OCSiAl); Surfactant: Polyether copolymer based surfactant.

The core-shell particles have been manufactured as follows: Nylon 6 particles were coated with SWCNTs to obtain the Nylon6/CNT core-shell particles wherein a w/w ratio between the core and the shell is about 100:1-10:1. The chemical compositions of the exemplary core-shell particles are identical with the compositions of articles presented in Table 1 below.

In an exemplary embodiment, an article of the invention has been manufactured via extrusion of exemplary core-shell particles in a twin screw extruder, (Coperion, ZSK 18MegaLab, D=18 mm, 48L/D) under appropriate conditions.

The extrudate has been subsequently dried at about 40-100° C. for about 0.5-10 h.

The dried extrudate has been further shaped (e.g., by compression molding) to obtain 10 cm*10 cm plaques (thickness of about 300 μm). EMI attenuation of the exemplary articles has been tested as described hereinbelow and compared to the EMI attenuation of (i) pristine polymer devoid of CNT, and (ii) a similar article having the same composition and with non-homogenously dispersed CNT (denoted as P9-158-1).

P9-158-1 has been prepared by molding (e.g., by compression molding) of a mixture composed of polyamide 6 and 0.2% CNT by weight, to obtain a non-homogeneous 10 cm*10 cm plaques (thickness of about 300 μm).

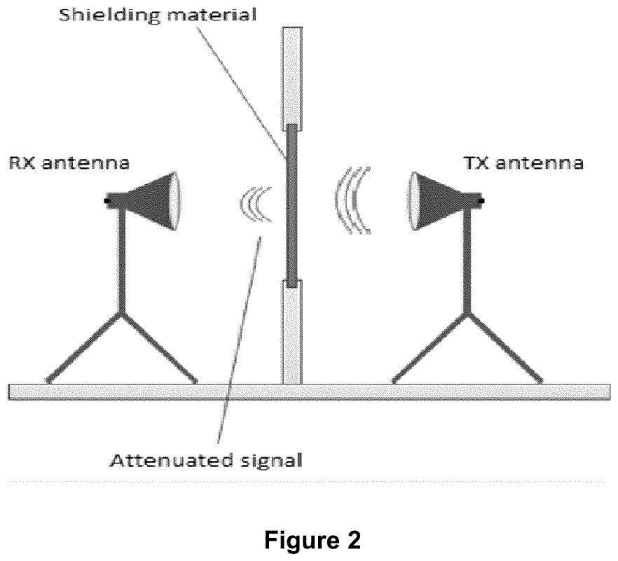

The measurements were performed in the labs of the Schlesinger Center for Radiation Sources and Applications at Ariel University, Israel. In brief, a transmission antenna and a receiving antenna connected to the network analyzer are aligned to each other (as presented by FIG. 2). Calibration measurements S21 take place without a test plate (free field).

For the measurement, the test plate is introduced into the center of the radiation field perpendicular to the antennas, such that the center of the test plate is positioned on an imaginary straight line between the transmission antenna and the receiving antenna.

The specimen is aligned level with and perpendicular to the electromagnetic wave's direction of transmission. The transmission properties are obtained by measuring the S21 parameters on the network analyzer.

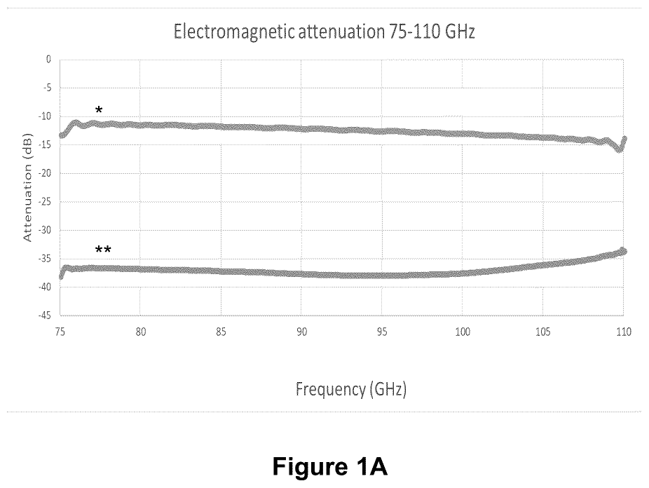

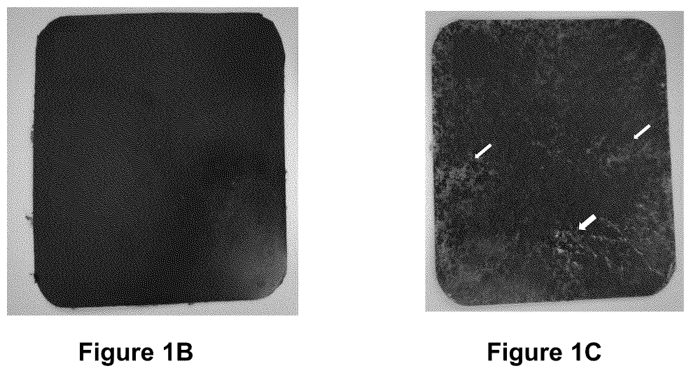

The results of this experiment are presented in FIG. 1A. The values in FIG. 1A are referred to EMI attenuation relative to the attenuation of the pristine polymer. As shown in FIG. 1A, within the entire tested wavelength range an exemplary article of the invention exhibited EMI attenuation being between 2-5 orders of magnitude greater than the EMI attenuation of the non-homogenous control.

Table 1 below presents exemplary compositions of the articles of the invention, showing high EMI shielding even at low CNT concentrations of between 0.005-1 wt %.

TABLE 1
compositions and EMI attenuation (between 75 and
110 GHz) of exemplary articles of the invention

| Polymer | PA6* | PA6 | PA6 | PA6* | PA6*(P9-158-1) |
|---|---|---|---|---|---|
| Length (cm) | 10 | 10 | 10 | 13 | 10 |
| Width (cm) | 10 | 10 | 10 | 7.5 | 10 |
| Thickness (cm) | 0.03 | 0.03 | 0.05 | 0.2 | 0.03 |
| Density (g/cm3) | 1.4 | 1.11 | 1.10 | 1.55 | 1.85 |
| Weight PA6 (g) | 3.24 | 3.24 | 5.4 | 22.23 | 5.55 |
| % wt. CNT | 0.20% | 1% | 0.10% | 0.05% | 0.2%** |
| Attenuation (dB) | 32 | 35 | 30.76 | 18.98 | 7.6 |

*the sample further comprises glass fibers;
**CNT distribution is not homogenous

The pristine polymer with substantially the same dimensions as the tested specimens, showed a negligible attenuation (about 0-5 dB).

1. An article comprising a wall, the wall comprises a polymeric matrix and a plurality of CNTs homogenously dispersed within said polymeric matrix, wherein:
said polymeric matrix comprises a thermoplastic polymer in a form of a three-dimensional interconnecting network;
a weight portion of said CNT relative to the polymeric matrix is between 0.00001 and 5%;
said polymeric matrix further comprises a surfactant; and
said article is configured for attenuation of an electromagnetic radiation at a wavelength range of between 1 kHz and 150 GHz.

2. The article of claim 1, wherein said thermoplastic polymer is characterized by a surface resistivity of at least 10¹⁰ ohm*cm.

3. The article of claim 1, wherein the matrix is devoid of coalesced particles of said thermoplastic polymer.

4. The article of claim 1, wherein said wall is characterized by a thickness between 100 nm and 10 mm, and wherein said CNT comprise a single-wall CNT (SWCNT).

5. The article of claim 1, wherein a weight ratio of said CNTs per area of said article is between 0.05 and 75 g/m² at a thickness of between 40 μm and 1 mm.

6. The article of claim 1, wherein a w/w ratio of said surfactant to said CNT within said wall is between 10:1 and 0.5:1.

7. The article of claim 1, wherein a w/w ratio of said surfactant to said polymer within said wall is between 0.00001% and 10%.

8. The article of claim 1, wherein said thermoplastic polymer is characterized by a melting temperature of at least 100° C.

9. The article of claim 1, wherein said article further comprises an inorganic material in a form of (i) fibers; (ii) particulate matter, or both; optionally wherein said inorganic material comprises any one of glass, metal, mineral and ceramic, or any combination thereof.

10. (canceled)

11. The article of claim 1, wherein said article is in a form of a film; optionally further comprising an additional layer in contact with at least one surface of said wall; further optionally wherein said additional layer comprises a polymer, and optionally comprises a high strength polymer, an inorganic material or both.

12. (canceled)

13. (canceled)

14. The article of claim 1, wherein said article is bondable to a substrate, wherein said bondable is via physical or chemical adhesion, or melting.

15. The article of claim 1, wherein said attenuation is at least 5 dB, as compared to a similar article devoid of the CNT.

16. The article of claim 15, wherein said attenuation is at least 10 dB at a wavelength of the electromagnetic radiation ranging between 1 and 110 GHz.

17. The article of claim 1, wherein each of (i) CNT and (ii) surfactant is present within said wall at a w/w concentration of between 0.00001% and 2%; and wherein said article is characterized by surface resistivity of between 10² and 10¹² ohm*cm.

18. (canceled)

19. The article of claim 1, wherein said wall substantially maintains property of the thermoplastic polymer devoid of the surfactant and the CNT, wherein said property is any one of: tensile strength, Young's modulus, elongation at break, melt strength or any combination thereof.
